(19) United States
(12) Patent Application Publication
(10) Pub. No.: US 2021/0109131 A1
(43) Pub. Date: Apr. 15, 2021

(54) WIRELESS POWER SENSOR

(71) Applicant: LG ELECTRONICS INC., Seoul (KR)

(72) Inventor: Moonshick CHUNG, Seoul (KR)

(73) Assignee: LG ELECTRONICS INC., Seoul (KR)

(21) Appl. No.: 17/070,495

(22) Filed: Oct. 14, 2020

(30) Foreign Application Priority Data
Oct. 14, 2019 (KR) 10-2019-0127325
Nov. 6, 2019 (KR) 10-2019-0141161

(51) Int. Cl. G01R 15/18; H02J 50/00

(52) U.S. Cl. CPC G01R 15/183; H02J 50/001; G01R 15/186

(57) ABSTRACT

A wireless power sensor including a current transformer including a first coil configured to output a first induced current generated by a magnetic field induced from an alternative current (AC) power line and including a second coil configured to output a second induced current generated by the magnetic field induced from the AC power line; an energy harvesting circuit configured to convert the first induced current into an amplified driving power voltage; and a wireless transmission controller configured to operate using the driving power voltage, generate measurement data corresponding to the second induced current, and transmit the measurement data to an external device.

### CROSS-REFERENCE TO RELATED APPLICATIONS

Pursuant to 35 U.S.C. § 119(a), this application claims the benefit of the earlier filing date and the right of priority to Korean Patent Application Nos. 10-2019-0127325 filed on Oct. 14, 2019 and 10-2019-0141161 filed on Nov. 6, 2019, both filed in the Republic of Korea, the contents of which are incorporated by reference herein in their entirety.

### BACKGROUND OF THE INVENTION

### 1. Field of the Invention

The present disclosure relates to a wireless power sensor, and more particularly, to a wireless power sensor that is easy to simultaneously perform energy harvesting and current measuring by a first induced current and a second induced current output from a current transformer.

### 2. Discussion of the Related Art

Internet of Things (IoT) technology, where all things are connected to exchange information in real time, is attracting attention as a core technology of the 4th industrial revolution. In terms of hardware, a development of wireless sensor network technology that exchanges information wirelessly should be supported, and for its wide application, a need for an autonomous independent power source capable of driving sensors and performing wireless communication by autonomously generating a power source has become rapidly emerging.

Current technology uses a battery, but since the battery has a limited time to use, a person continuously manages a power state of each sensor node even after a wireless sensor network is installed.

An energy harvesting technology that converts various energy sources (temperature, sunlight, vibration, sound waves, electromagnetic waves, stray magnetic fields, etc.) that are not used in everyday life into usable forms of electric energy is attracting attention as an element technology of autonomous independent power source technology for driving IoT (Internet of Things) wireless sensor networks.

Magnetic field noise is inevitably generated in all machines, facilities, and electronic products that use electricity, but power conversion is not efficiently performed by electromagnetic induction elements composed of wire coils and magnetic core with a magnitude of a magnetic field of several Gauss or less, and an installation environment is limited due to their sizes and weights.

In general, sensors that perform energy harvesting by applying an energy harvesting technology operate by separating an energy harvesting section and a measuring section from each other in order to simultaneously perform energy harvesting and current measuring. In recent years, research is underway to independently performing energy harvesting and current measuring without distinguishing between the energy harvesting section and the measurement section.

### SUMMARY OF THE INVENTION

An aspect of the present disclosure is to provide a wireless power sensor that is easy to simultaneously perform energy harvesting and current measuring by a first induced current and a second induced current output from a current transformer.

In addition, an aspect of the present disclosure is to provide a wireless power sensor that outputs a first induced current for energy harvesting and a second induced current for current measuring from a coil wound around a lower core included in a current transformer.

In addition, an aspect of the present disclosure is to provide a wireless power sensor in which a lower core included in a current transformer includes a first lower core and a second lower core having a ‘ [symbol] ’ shape to output a first induced current and a second induced current.

In addition, an aspect of the present disclosure is to provide a wireless power sensor in which an antenna pattern for wirelessly transmitting measurement data on a measured current is formed on an outer side surface of a lower case.

However, aspects of the present disclosure are not limited to the above aspects, and other aspects that are not mentioned will be clearly understood with the following description.

A wireless power sensor according to a first embodiment of the present disclosure may include a current transformer configured to output a first induced current and a second induced current generated by a magnetic field induced from an alternative current (AC) power line, an energy harvesting circuit portion configured to generate a driving power source by the first induced current, and a wireless transmission controller configured to operate by the driving power source and transmit measurement data corresponding to the second induced current to an external device.

The current transformer may include an upper core, a lower core, and a coil wound around the lower core and outputting the first induced current and the second induced current generated by the magnetic field flowing through the upper core and the lower core.

The coil may include a first coil outputting the first induced current, and a second coil that is commonly grounded with the first coil by a center tap and outputting the second induced current.

A number of turns of the first coil may be 1 to 4 times a number of turns of the second coil.

The lower core may include a first lower core around which the first coil is wound, and a second lower core formed between the upper core and the first lower core and around which the second coil is wound.

The first lower core may be thicker than a thickness of the second lower core or wider than a width of the second lower core.

The energy harvesting circuit portion may include a voltage doubler circuit portion configured to double a first voltage corresponding to the first induced current to a second voltage, a time delay circuit portion configured to output the second voltage when the second voltage is higher than a set reference voltage, and a linear regulator configured to convert the second voltage output from the time delay circuit portion into the driving power source to output the driving power source.

The time delay circuit portion may include a switch circuit configured to perform a turn-on operation when the second voltage is higher than the reference voltage to output the second voltage to the linear regulator.

The switch circuit may include a delay capacitor configured to charge the second voltage to be higher than the reference voltage, and a switch element configured to perform a turn-on operation when a charged voltage charged in the delay capacitor is higher than the reference voltage to output the second voltage to the linear regulator.

The linear regulator may convert the second voltage into the driving power source by dropping the second voltage by a predetermined voltage, then output the driving power source to the wireless transmission controller.

The wireless transmission controller may include a sensing resistor configured to sense the second induced current, an analog-to-digital (AD) converter configured to convert an analog-type current signal sensed by the sensing resistor into a digital signal, and a data generator configured to operate by the driving power source to generate the measurement data corresponding to the digital signal, then transmit the measurement data to the external device.

The coil may include a first coil outputting the first induced current and a second coil outputting the second induced current, and the sensing resistor may be connected to both ends of the second coil.

A wireless power sensor according to a second embodiment of the present disclosure may include an upper case with a current transformer configured to output a first induced current and a second induced current generated by a magnetic field induced from an alternative current (AC) power line being installed therein, and a lower case detachable from the upper case and provided with a printed circuit board having an energy harvesting circuit portion configured to generate a driving power source by the first induced current and a wireless transmission controller configured to operate by the driving power source to generate measurement data corresponding to the second induced current. And, on an outer surface of the lower case, an antenna pattern configured to transmit the measurement data generated by the wireless transmission controller to an external device may be formed.

The antenna pattern may be formed on at least one of outer surfaces of the lower case.

The printed circuit board may be provided with an impedance matching pattern resonating with the antenna pattern, and the antenna pattern may be connected to the impedance matching pattern through a via hole formed in the lower case to transmit the measurement data at a set resonance frequency.

In addition, the wireless power sensor may further include a C-Clip inserted into the lower case and configured to electrically connect the impedance matching pattern and the antenna pattern.

The antenna pattern may be electrically connected to the C-Clip by being brought into contact with a copper foil pattern formed on an inner side surface of the via hole, or by being brought into contact with a conductive metal inserted into the inner side surface of the via hole.

The impedance matching pattern may include an inductor corresponding to the resonance frequency, and an LC resonance circuit on which a capacitor is mounted.

A wireless power sensor according to the present disclosure has an advantage of simultaneously performing energy harvesting and current measuring by simultaneously outputting a first induced current for energy harvesting and a second induced current for current measuring by a first coil and a second coil wound around a lower core.

In addition, the wireless power sensor according to the present disclosure has an advantage of attenuating noise caused by current measuring when performing energy harvesting, due to a first coil and a second coil being connected to a lower core by a center tap, or each of the first coil and the second coil being wound around each of a first lower core and a second lower core.

In addition, the wireless power sensor according to the present disclosure has an advantage of being stably started by charging a second voltage to a reference voltage or higher to generate a driving power source when a first induced current is lower than a set current.

In addition, the wireless power sensor according to the present disclosure has an advantage of having a simple circuit configuration and saving manufacturing cost by being provided with a sensing resistor to sense a second induced current when measuring current.

In addition, the wireless power sensor according to the present disclosure has an advantage of reducing a volume occupied by the related art small helical antenna by forming an antenna pattern on an outer side of a lower case including a printed circuit board to connect the antenna pattern to an impedance matching pattern formed on the printed circuit board.

In addition, the wireless power sensor according to the present disclosure has an advantage of securing coupling stability by connecting an extended antenna pattern and an impedance matching pattern to a via hole formed in a lower case by a C-Clip.

In addition, the wireless power sensor according to the present disclosure has an advantage of increasing a degree of freedom in antenna design, such as changing a shape of an antenna and increasing a length of a pattern, while maintaining a compact miniaturization product design concept of the wireless power sensor, and improving wireless transmission and reception performance, by forming the antenna pattern on an outer side surface of a lower case.

In addition, the wireless power sensor according to the present disclosure has an advantage of improving communication margin and communication stability by an antenna pattern being formed on an outer side surface of a lower case, so that there is no interference with cores, coils, and components mounted on a printed circuit board, thereby minimizing degradation in a performance due to the components, increasing power intensity, and improving characteristics of a radiation pattern by radiating a radio signal into a space.

In addition, various effects other than the above-described effects may be directly or implicitly disclosed in a detailed description according to embodiments of the present disclosure to be described later.

### BRIEF DESCRIPTION OF THE DRAWINGS

FIG. 1 is a perspective view illustrating a wireless power sensor according to a first embodiment of the present disclosure.

FIGS. 2 and 3 are sectional views illustrating a wireless power sensor illustrated in FIG. 1.

FIG. 4 is a block diagram illustrating a control configuration of a wireless power sensor illustrated in FIG. 1.

FIG. 5 is a circuit diagram illustrating a circuit configuration included in a wireless power sensor illustrated in FIG. 1.

FIG. 6 is a timing diagram illustrating a first induced current and a second induced current illustrated in FIG. 5.

FIGS. 7 to 9 are exemplary views illustrating operations of a wireless power sensor according to a first embodiment of the present disclosure.

FIG. 10 is a perspective view illustrating a wireless power sensor according to a second embodiment of the present disclosure.

FIGS. 11 and 12 are sectional views illustrating a wireless power sensor illustrated in FIG. 10.

### DETAILED DESCRIPTION OF THE EMBODIMENTS

In the following description, it should be noted that only parts needed in understanding the embodiments of the present disclosure will be described, and descriptions of other parts will be omitted so as not to divert the gist of the present disclosure. Terms or words used in this specification and claims described below should not be construed as being limited to a conventional or dictionary meaning, and it should be interpreted as a meaning and concept consistent with the technical idea of the present disclosure on the basis of the principle that an inventor can properly define the concept of terms in order to explain his or her disclosure in the best way. Therefore, the embodiments described in this specification and the configurations illustrated in the drawings are only preferred embodiments of the present disclosure, and do not represent all the technical ideas of the present disclosure, and it should be understood that there may be various equivalents and variations that can replace them at the time of application.

Hereinafter, embodiments of the present disclosure will be described in more detail with reference to the accompanying drawings.

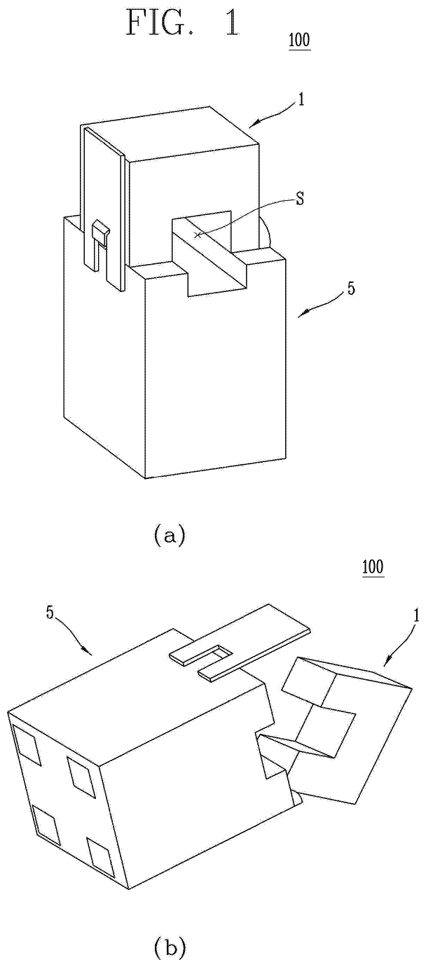

FIG. 1 is a perspective view illustrating a wireless power sensor according to a first embodiment of the present disclosure. Referring to FIG. 1, a wireless power sensor 100 includes an upper case 1 and a lower case 5. In particular, (a) of FIG. 1 is a view in which the upper case 1 and the lower case 5 are coupled, and (b) of FIG. 1 is a view in which the upper case 1 and the lower case 5 are decoupled. FIG. 1 represents one embodiment and may be different according to a coupling method, but is not limited thereto.

When the upper case 1 and the lower case 5 are coupled, a space S through which an alternative current (AC) power line passes is formed in the wireless power sensor 100. The wireless power sensor 100 can output a first induced current and a second induced current generated by a magnetic field induced from the AC power line.

The upper case 1 includes an upper core mounted therein, and the lower case 5 includes a lower core around which a coil outputting the first induced current and the second induced current is wound and a printed circuit board mounted therein. A coupling member for coupling can be formed in the upper case 1 and the lower case 5.

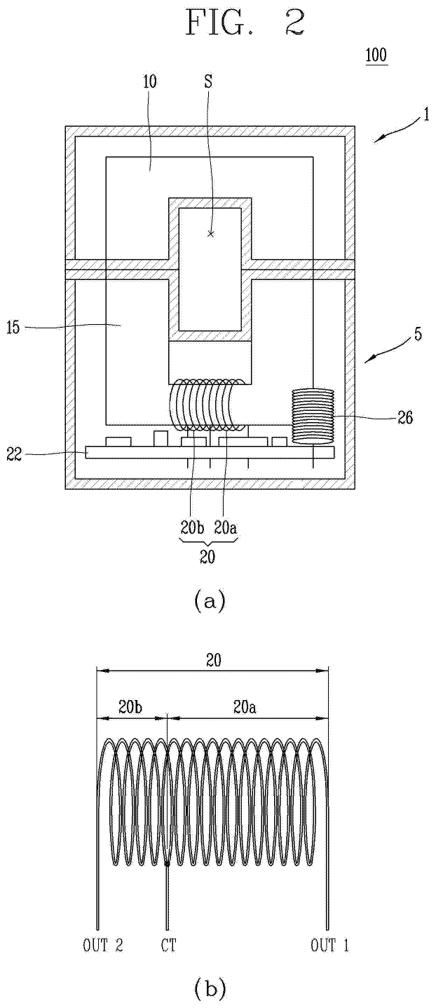

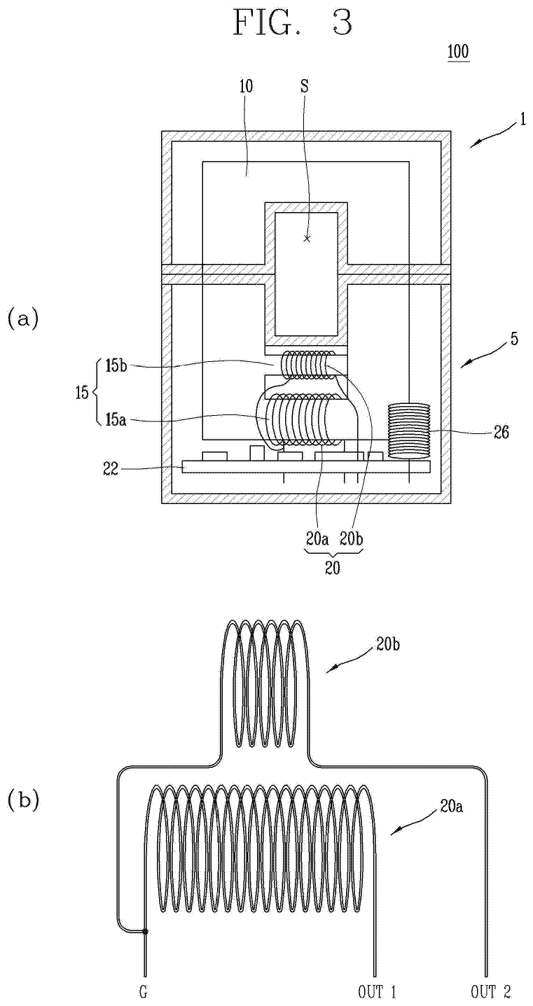

FIGS. 2 and 3 are sectional views illustrating the wireless power sensor illustrated in FIG. 1. Here, (a) of FIG. 2 is a sectional view of the wireless power sensor 100, and (b) of FIG. 2 is a view illustrating a coil 20. Referring to FIG. 2, the wireless power sensor 100 includes an upper core 10, a lower core 15, a coil 20, a printed circuit board 22, and an antenna 26. The printed circuit board 22 may have semiconductor elements, such as passive elements and IC chips, forming a harvesting circuit portion and a wireless transmission controller to be described later mounted thereon.

The coil 20 may include a first coil 20a and a second coil 20b. The first coil 20a outputs a first induced current corresponding to a magnetic field induced from an AC power line, and the second coil 20b outputs a second induced current corresponding to the magnetic field induced from the AC power line.

The first induced current is transmitted to the harvesting circuit portion mounted on the printed circuit board 22 to generate a driving power source, and the second induced current may be a current for measuring a current flowing through the AC power line from the wireless transmission controller operated by the driving power source generated by the harvesting circuit portion. Here, a center tap CT of the first coil 20a and the second coil 20b can be commonly connected to a ground of the printed circuit board 22.

A first output end OUT 1 of the first coil 20a transmits the first induced current to an energy harvesting circuit portion, and a second output end OUT 2 of the second coil 20b transmits the second induced current to the wireless transmission controller. In an embodiment, the first coil 20a and the second coil 20b may be integrally formed or connected to each other through the center tap CT while being separated from each other, but is not limited thereto.

Here, a number of turns of the first coil 20a is 1 to 4 times a number of turns of the second coil 20b, but is not limited thereto. When the number of turns of the first coil 20a is less than 1 times the number of turns of the second coil 20b, an inductance may affect when the harvesting circuit portion generates a driving power source. Also, when the number of turns of the first coil 20a is more than 4 times the number of turns of the second coil 20b, an inductance may not affect when the harvesting circuit portion generates a driving power source, but an efficiency may not be high as a size of the lower core 15 increases.

In addition, the antenna 26 can transmit measurement data obtained by measuring the second induced current generated by the wireless transmission controller to an external device. For example, the antenna 26 may be a small helical type antenna, but is not limited thereto.

In addition, (a) of FIG. 3 is a sectional view of the wireless power sensor 100, and (b) of FIG. 3 is a view illustrating the coil 20. Referring to FIG. 3, the wireless power sensor 100 includes the upper core 10, the lower core 15, the coil 20, the printed circuit board 22, and the antenna 26.

The upper core 10, the printed circuit board 22, and the antenna 26 are illustrated in FIG. 2, and description thereof will be omitted. As shown, the lower core 15 may include a first lower core 15a and a second lower core 15b. The first lower core 15a and the second lower core 15b each represents a portion where each of the first coil 20a and the second coil 20b is wound around.

The first lower core 15a may have the first coil 20a wound therearound, and may have a thickness or a width greater than that of the second lower core 15b around which the second coil 20b is wound, but is not limited thereto. In addition, the first coil 20a and the second coil 20b may be connected to a ground end G to be commonly connected to the ground of the printed circuit board 22. In addition, the first output end OUT 1 of the first coil 20a can output the first induced current, and the second output end OUT 2 of the second coil 20b can output the second induced current.

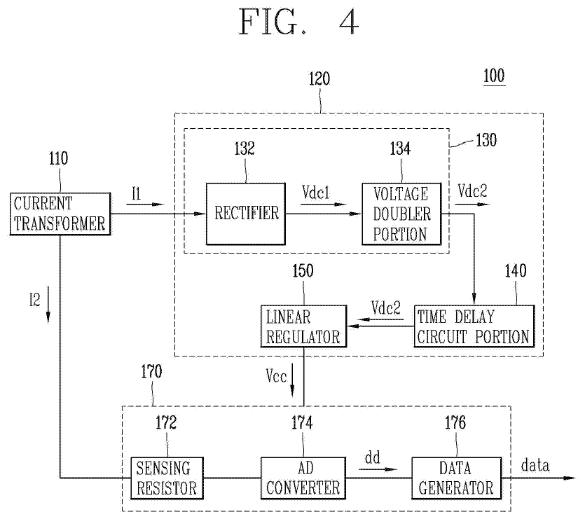

Next, FIG. 4 is a block diagram illustrating a control configuration of the wireless power sensor illustrated in FIG. 1. Referring to FIG. 4, the wireless power sensor 100 includes a current transformer 110, an energy harvesting circuit portion 120, and a wireless transmission controller 170.

The current transformer 110 may include the upper core 10, the lower core 15, and the coil 20 illustrated in FIGS. 2 and 3. The current transformer 110 can also be coupled to an AC power line to output a first induced current I1 and a second induced current I2 induced by a magnetic field generated from a current flowing through the AC power line.

The current transformer 110 can be implemented as the lower core 15 as illustrated in FIGS. 2 and 3, and the coil can may include the first coil 20a and the second coil 20b configured to output the first induced current I1 and the second induced current I2.

Further, the energy harvesting circuit portion 120 may include a voltage doubler circuit portion 130, a time delay circuit portion 140, and a linear regulator 150. The voltage doubler circuit portion 130 may include a rectifier 132 and a voltage doubler portion 134.

The rectifier 132 converts a first voltage Vac corresponding to the first induced current I1 into a dc voltage Vdc1. The rectifier 132 may be a bridge circuit implemented as a plurality of diodes or switch elements, but is not limited thereto. In addition, the rectifier 132 may include a smoothing capacitor that smooths the dc voltage Vdc1.

The voltage doubler portion 134 doubles the dc voltage Vdc1 to a second voltage Vdc2. The voltage doubler portion 134 may double or quadruple the dc voltage Vdc1, but is not limited thereto. In addition, the time delay circuit portion 140 delays a time until the second voltage Vdc2 rises above a set reference voltage, and then outputs the second voltage Vdc2.

That is, the time delay circuit portion 140 may include a switch circuit configured to perform a turn-on operation when the second voltage Vdc2 is higher than the reference voltage to output the second voltage Vdc2 to the linear regulator 150. The switch circuit may include a delay capacitor configured to charge the second voltage Vdc2 to be higher than the reference voltage, and a switch circuit configured to output the second voltage Vdc2 to the linear regulator 150 when a charged voltage charged in the delay capacitor is higher than the reference voltage.

Also, a charging capacity of the delay capacitor may vary according to the reference voltage, but is not limited thereto. In addition, the time delay circuit portion 140 may delay time by passive elements such as the delay capacitor and a resistor in order to supply a power source to the switch element during initial startup, but is not limited thereto.

Further, the linear regulator 150 converts the second voltage Vdc2 output from the time delay circuit portion 140 into a driving power source Vcc. That is, the linear regulator 150 outputs the driving power source Vcc that has dropped by a predetermined voltage when the driving power source Vcc is generated by the second voltage Vdc2.

As shown in FIG. 4, the wireless transmission controller 170 includes a sensing resistor 172, an analog-to-digital (AD) converter 174, and a data generator 176. The sensing resistor 172 is connected to both ends of the second coil 20b. That is, as described in FIG. 2, when the second coil 20b is connected to the center tap CT, the sensing resistor 172 is connected between the center tap CT and the second output end OUT 2 to sense the second induced current I2.

In addition, as described in FIG. 3, when the first coil 20a and the second coil 20b are connected to the ground end G, the sensing resistor 172 is connected between the ground end G and the second output end OUT 2 to sense the second induced current I2. In other words, the sensing resistor 172 may be a resistor for measuring the second induced current I2.

An AD converter 174 can convert an analog-type current signal flowing through the sensing resistor 172 into a digital signal. That is, the AD converter 174 can convert an analog-type current signal into a digital signal dd corresponding to the analog type by sampling the analog-type current signal according to a set sampling number.

In addition, the data generator 176 operates by the driving power source Vcc output from the linear regulator 150 to generate measurement data corresponding to the digital signal dd. The data generator 176 can read values of the digital signal dd to generate measurement data corresponding to the values of the digital signal dd.

The measurement data may correspond to the second induced current I2 and correspond to a current flowing through the AC power line. Thereafter, the data generator 176 can radiate the measurement data to the antenna 26 to transmit the data to an external device.

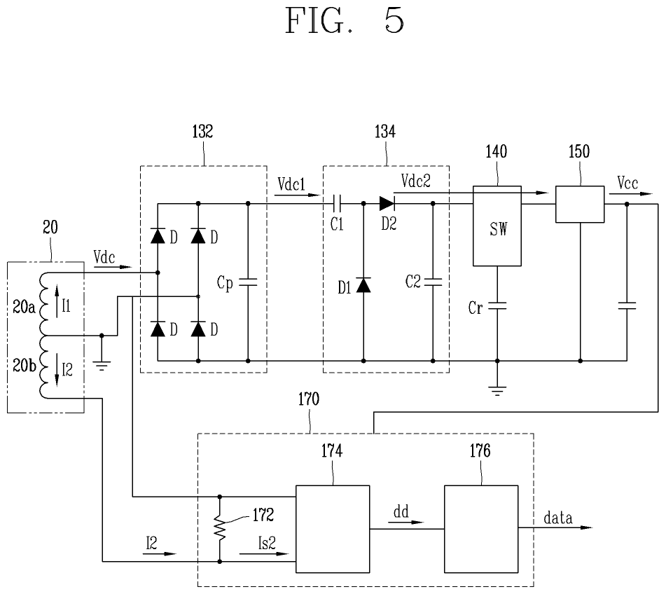

Next, FIG. 5 is a circuit diagram illustrating a circuit configuration included in the wireless power sensor illustrated in FIG. 1. Referring to FIG. 5, the wireless power sensor 100 may include a coil 20 including the first coil 20a and the second coil 20b, the energy harvesting circuit portion 120 including the voltage doubler circuit portion 130, the time delay circuit portion 140, and the linear regulator 150, and the wireless transmission controller 170.

The first coil 20a and the second coil 20b are secondary coils of the current transformer 110 and output the first induced current I1 and the second induced current I2. The voltage doubler circuit portion 130 includes the rectifier 132 and the voltage doubler portion 134.

Further, the rectifier 132 converts the first voltage Vac corresponding to the first induced current I1 output from the first coil 20a into the dc voltage Vdc1. In FIG. 5, the rectifier 132 is a bridge circuit implemented as a plurality of diodes D. In addition, the rectifier 132 includes a smoothing capacitor Cp that smooths the dc voltage Vdc1.

In addition, the voltage doubler portion 134 doubles the dc voltage Vdc1 to the second voltage Vdc2. In particular, the voltage doubler portion 134 can output the second voltage Vdc2 obtained by doubling the dc voltage Vdc1. In FIG. 5, the voltage doubler portion 134 includes a first capacitor C1, a second capacitor C2, a first diode D1, and a second diode D2.

In an embodiment, the voltage doubler portion 134 represents a voltage doubler circuit, but for a voltage quadrupler circuit, a number of capacitors and a number of diodes may be different, and is not limited thereto. In addition, the first capacitor C1 is connected to the rectifier 132, and the first diode D1 and the second diode D2 are connected to one side of the first capacitor C1. Also, the second capacitor C2 is connected to the second diode D2.

Further, the time delay circuit portion 140 can delay time until the second voltage Vdc2 rises above the set reference voltage, and then output the second voltage Vdc2. in FIG. 5, the time delay circuit portion 140 includes a delay capacitor Cr configured to charge the second voltage Vdc2 to be higher than the reference voltage, and a switch circuit SW configured to output the second voltage Vdc2 to the linear regulator 150 when the charged voltage charged in the delay capacitor Cr is higher than the reference voltage.

Also, the switch element SW may be a reset IC that operates when the charged voltage charged in the delay capacitor Cr is greater than or equal to the reference voltage, but is not limited thereto. In addition, the time delay circuit portion 140 may be implemented as a passive element such as the delay capacitor Cr and a resistor, and can delay to output the second voltage Vdc.

The linear regulator 150 can convert the second voltage Vdc2 output from the time delay circuit portion 130 into a driving voltage Vcc. That is, the linear regulator 150 can output the driving power source Vcc that has dropped by a predetermined voltage when the driving power source Vcc is generated by the second voltage Vdc2.

As shown in FIG. 5, the wireless transmission controller 170 includes the sensing resistor 172, the AD converter 174 and the data generator 176. The sensing resistor 172 is connected between the second output end OUT 2 of the second coil 20b and the center tap CT or the ground end G.

When the second induced current I2 output from the second coil 20b is input, the sensing resistor 172 outputs an analog-type current Is2. The analog-type current Is2 may be a current flowing to the sensing resistor 172, but is not limited thereto.

In addition, the AD converter 174 converts the current Is2 into the digital signal dd. Thereafter, the data generator 174 generates measurement data corresponding to the digital signal dd to transmit the measurement data to an external device through the antenna 26.

In an embodiment, the AD converter 174 and the data generator 174 are described as separate configurations, but may be implemented as a single processor, and is not limited thereto. That is, the wireless transmission controller 170 operates by the driving power source Vcc and can transmit measurement data to an external device through the antenna 26 at predetermined time intervals. Here, after an initial start-up is completed, the wireless transmission controller 170 can control the second voltage Vdc2 to be supplied to the linear regulator 150 without a time delay by operating the time delay circuit portion 140.

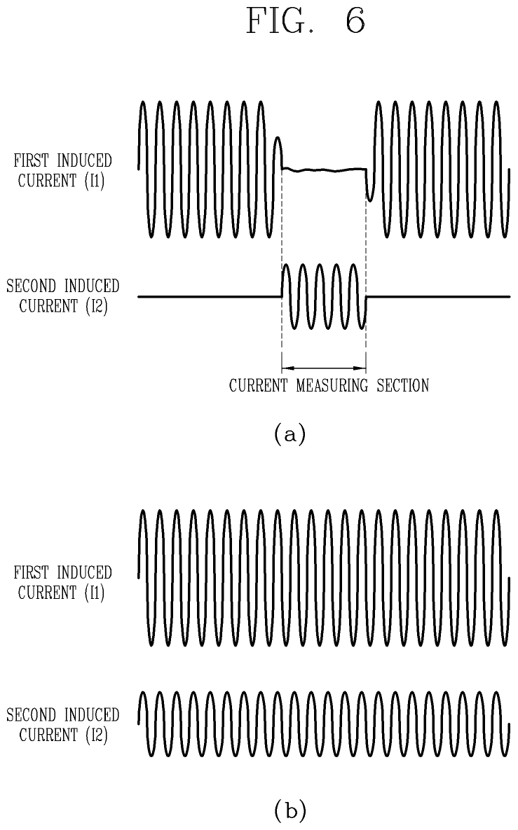

Next, FIG. 6 is a timing diagram illustrating the first induced current and the second induced current illustrated in FIG. 5. In particular, (a) of FIG. 6 illustrates the first induced current I1 and the second induced current I2 that are generally output from each coil, and (b) of FIG. 6 illustrates the first induced current I1 and the second induced current I2 output by applying the first coil 20a and the second coil 20b according to the present disclosure.

That is, referring to (a) of FIG. 6, the first induced current I1 is a current to generate the driving power source Vcc to be supplied to the wireless transmission controller 170, and the second induced current I2 is a current to measure a current flowing through the AC power line to generate measurement data. In general, the wireless power sensor responds by classifying a harvesting mode for generating a driving power source Vcc and a measurement mode for generating measurement data, so that the mode in a current measuring section in (a) of FIG. 6 is converted.

Here, as illustrated in (a) of FIG. 6, a stable analog-type current signal is generated in the current measuring section, so that measurement data can be normally generated. However, at an entry point of the current measuring section, a signal level of the current signal may not be stable, and a circuit may be implemented by further including a switch element for mode conversion.

Here, the first induced current I1 and the second induced current I2 in (b) of FIG. 6 are output from each of the first coil 20a and the second coil 20b, and the first induced current I1 can be stably supplied to the harvesting circuit portion and the second induced current I2 can be supplied to the wireless transmission controller 170 without performing the mode conversion as in (a) of FIG. 6.

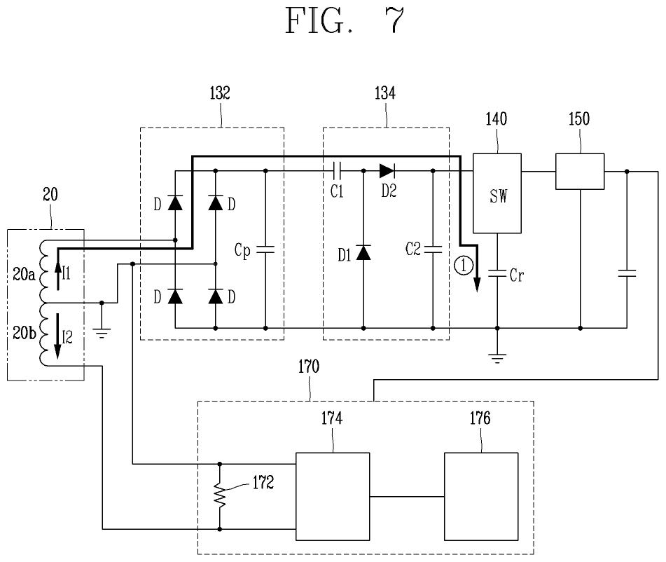

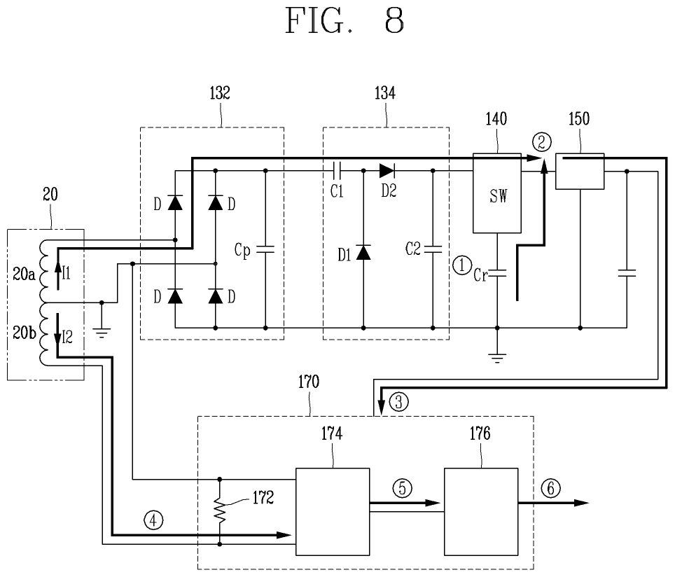

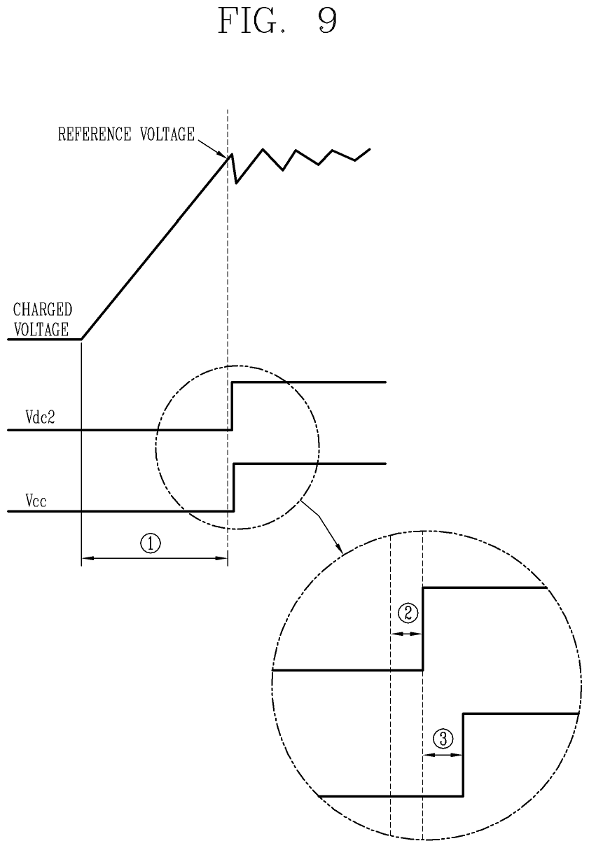

Next, FIGS. 7 to 9 are exemplary views illustrating operations of the wireless power sensor according to the present disclosure. In particular, FIGS. 7 to 9 are exemplary views illustrating operations of the wireless power sensor according to the present disclosure. Firstly, FIGS. 7 and 8 illustrate a current path of the circuit diagram illustrated in FIG. 5, and FIG. 9 is a timing diagram illustrating a charged current charged in the delay capacitor Cr, a time point in which the second voltage Vdc is supplied, and a time point in which the driving voltage Vcc is supplied.

Referring to FIG. 7, the second voltage Vdc can be charged in the delay capacitor Cr of the time delay circuit portion 140, so that the second voltage Vdc obtained by doubling the first voltage Vac corresponding to the first induced current I1 when the wireless power sensor 100 is initially started rises by the set reference voltage. In particular, FIG. 7 illustrates a first current path \textcircled{1} to charge the second voltage Vdc2 in the delay capacitor Cr. Also, FIG. 9 illustrates that the second voltage Vdc2 charged in the delay capacitor Cr rises by a set reference voltage.

Since the switch element SW of the time delay circuit portion 140 is not operated by the second voltage Vdc2 in FIG. 9 and the switch element SW is not operated by the driving power source Vcc in FIG. 5, the linear regulator 140 does not operate. In addition, referring to FIG. 7, the second induced current I2 does not form a current path because the driving power source Vcc is not supplied to the wireless transmission controller 170.

In addition, FIG. 8 illustrates a second current path \textcircled{2} in which the charged voltage charged in the delay capacitor Cr rises by a set reference voltage, and the switch element SW operates to supply the second voltage Vdc2 to the linear regulator 150 \textcircled{2}. FIG. 8 also illustrates a third current path \textcircled{3} in which the driving power source Vcc is output to the wireless transmission controller 170 by an operation of the linear regulator 150 after the second current path \textcircled{2} is formed.

The second current path \textcircled{2} and the third current path \textcircled{3} may be formed with a predetermined time difference, but the time difference is very small and can be ignored. That is, as illustrated in FIG. 9, at a time point where the charged voltage is increased by the reference voltage, the second voltage Vdc2 can be supplied to the linear regulator 150 by the second current path \textcircled{2}, and the driving voltage Vcc can be supplied to the wireless transmission controller 170 by the third current path \textcircled{3}.

The wireless power sensor according to the embodiment has an advantage in that the wireless transmission controller 170 can be smoothly operated by supplying the second voltage Vdc2 corresponding to the first voltage Vac induced by a small current during initial startup with a time delay to generate a driving power source Vcc capable of driving the wireless transmission controller 170.

In addition, referring to FIG. 8, a fourth current path \textcircled{4} through which the second induced current I2 is supplied to the sensing resistor 172 can be formed. When the driving power source Vcc is supplied to the wireless transmission controller 170 to operate the wireless transmission controller 170, the fourth current path \textcircled{4} can be formed.

Thereafter, the AD converter 174 can form a fifth current path \textcircled{5} by converting the analog-type current supplied by the fourth current path \textcircled{4} into a digital signal dd to output the digital signal dd to the data generator 176. Finally, the data generator 176 may generate measurement data corresponding to the digital signal dd to transmit \textcircled{6} the measurement data to an external device. In an embodiment, the fifth current path \textcircled{5} may correspond to data communication, but is not limited thereto.

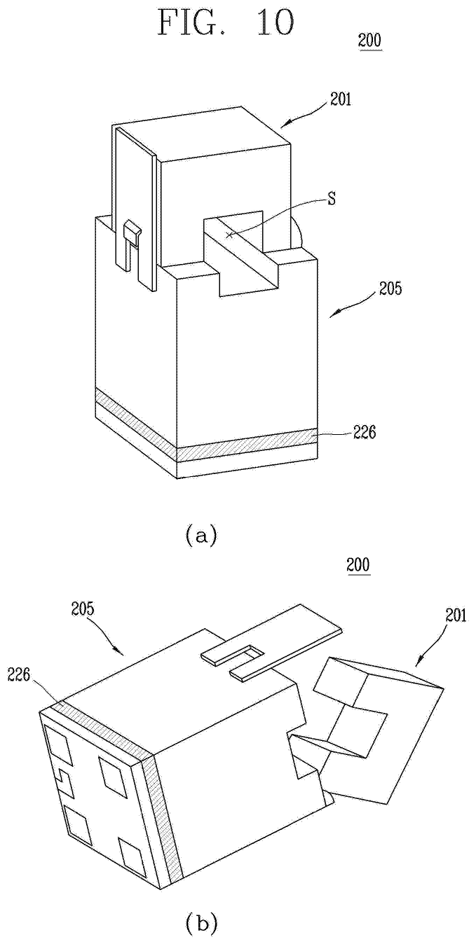

Next, FIG. 10 is a perspective view illustrating the wireless power sensor according to the second embodiment of the present disclosure. Referring to FIG. 10, a wireless power sensor 200 includes an upper case 201 and a lower case 205. In more detail, (a) of FIG. 10 is a view in which the upper case 201 and the lower case 205 are coupled, and (b) of FIG. 10 is a view in which the upper case 201 and the lower case 205 are decoupled. FIG. 10 represents one embodiment and may be different according to a coupling method, but is not limited thereto.

When the upper case 201 and the lower case 205 are coupled, the wireless power sensor 200 has a space S through which an AC power line passes. The wireless power sensor 200 can output a first induced current and a second induced current induced by a magnetic field flowing through the AC power line.

The upper case 201 may have an upper core mounted therein, and the lower case 205 may have a lower core around which a coil outputting the first induced current and the second induced current is wound, and a printed circuit board mounted therein. On an outer surface of the lower case 205, an antenna pattern 226 can be formed. That is, the antenna pattern 226 can transmit measurement data to an external device, similar to the antenna 26 described in FIGS. 1 to 3.

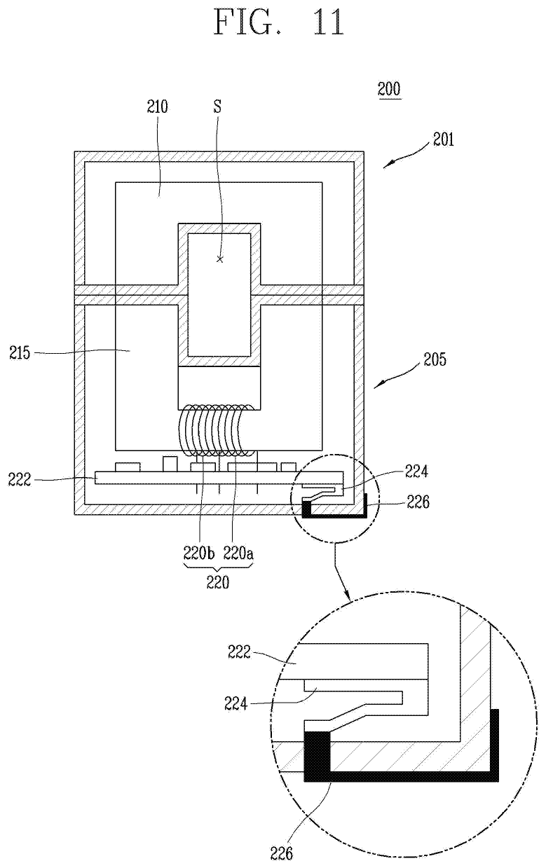

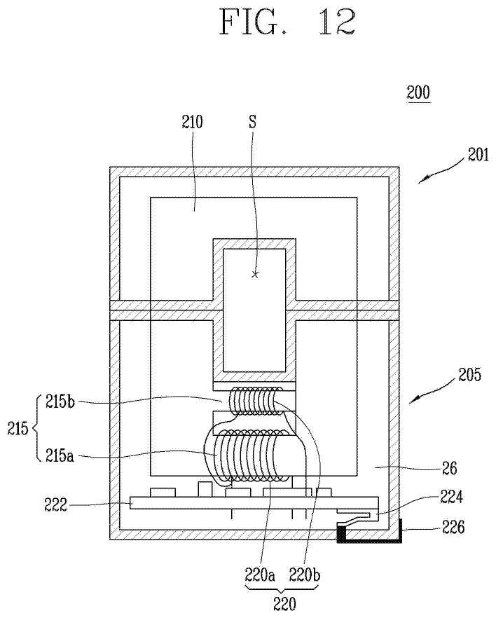

Next, FIGS. 11 and 12 are sectional views illustrating the wireless power sensor illustrated in FIG. 10. Referring to FIGS. 11 and 12, the wireless power sensor 200 includes an upper core 210, a lower core 215, a coil 220, a printed circuit board 222, and an antenna pattern 226.

The printed circuit board 222 may have semiconductor elements, such as passive elements and IC chips, forming a harvesting circuit portion and a wireless transmission controller to be described later mounted thereon. In addition, on the printed circuit board 222, an impedance matching pattern for impedance matching with the antenna pattern 226 can be formed.

The impedance matching pattern can be electrically connected to the antenna pattern 226 by a C-Clip 224. In addition, the impedance matching pattern can be a pattern for an LC resonance circuit including an inductor and a capacitor corresponding to a frequency of a radio signal, but is not limited thereto.

Further, the C-Clip 224 is mounted on a rear surface of the printed circuit board 222 and can be electrically contacted to the antenna pattern 226. The antenna pattern 226 can be formed on at least one of outer surfaces of the lower case 205, and transmit measurement data input through the impedance matching pattern to an external device while contacting the C-Clip 224 through a via hole formed in the lower case 205.

The antenna pattern 226 may be brought into contact with the C-Clip 224 by a copper foil pattern formed on an inner side surface of the via hole, or may be brought into contact with the C-Clip 224 by a conductive metal inserted into the inner side surface of the via hole. Also, a width and a length of the antenna pattern 226 can be determined according to a transmission frequency, but is not limited thereto. As such, the antenna pattern 226 formed on an outer side of the lower case 205 is connected to the impedance matching pattern formed on the printed circuit board 222, thereby reducing a volume thereof and reducing a noise of a signal.

In addition, the antenna pattern 226 can increase a degree of freedom in antenna design, such as changing a shape of an antenna and increasing a length of a pattern, while maintaining a compact miniaturization product design concept of the wireless power sensor 200, and can improve wireless transmission and reception performance. In addition, the upper core 210, the lower core 215 and the coil 220 can be formed in a same shape as the upper core 10, the lower core 15 and the coil 20 illustrated in FIG. 2, and detailed description is omitted.

Features, structures, effects, etc. described in the embodiments above are included in at least one embodiment of the present disclosure, and are not necessarily limited to only one embodiment. Further, the features, structures, effects, etc. illustrated in each embodiment may be combined or modified for other embodiments by those skilled in the art to which the embodiments belong. Accordingly, contents related to such combinations and modifications should be construed as being included in the scope of the present disclosure.

In addition, although the foregoing description has been given with reference to the embodiments, these are merely illustrative and do not limit the present disclosure, and it will be understood that those skilled in the art will be able to variously modify and change the present disclosure without departing from the essential characteristics of the embodiments. For example, each component specifically shown in the embodiments can be modified. And differences related to these modifications and applications should be construed as being included in the scope of the present disclosure defined in the appended claims.

What is claimed is:

1. A wireless power sensor, comprising:
a current transformer including a first coil configured to output a first induced current generated by a magnetic field induced from an alternative current (AC) power line and including a second coil configured to output a second induced current generated by the magnetic field induced from the AC power line;
an energy harvesting circuit configured to convert the first induced current into an amplified driving power voltage; and
a wireless transmission controller configured to operate using the driving power voltage, generate measurement data corresponding to the second induced current, and transmit the measurement data to an external device.

2. The wireless power sensor of claim 1, wherein the current transformer further comprises:
an upper core; and
a lower core, and
wherein the first coil and the second coil are wound around the lower core and output the first induced current and the second induced current generated by the magnetic field flowing through the upper core and the lower core.

3. The wireless power sensor of claim 2, wherein the second coil is commonly grounded with the first coil by a center tap.

4. The wireless power sensor of claim 3, wherein a number of turns of the first coil is 1 to 4 times a number of turns of the second coil.

5. The wireless power sensor of claim 3, wherein the lower core comprises:
a first lower core around which the first coil is wound; and
a second lower core formed between the upper core and the first lower core and around which the second coil is wound.

6. The wireless power sensor of claim 5, wherein a thickness of the first lower core is greater than a thickness of the second lower core or a width of the first lower core is greater than a width of the second lower core.

7. The wireless power sensor of claim 1, wherein the energy harvesting circuit portion comprises:
a voltage doubler circuit portion configured to double a first voltage corresponding to the first induced current to a second voltage;
a time delay circuit portion configured to output the second voltage when the second voltage is higher than a set reference voltage; and
a linear regulator configured to convert the second voltage output from the time delay circuit portion into the driving power voltage.

8. The wireless power sensor of claim 7, wherein the time delay circuit portion comprises a switch circuit configured to switch on when the second voltage is higher than the set reference voltage to output the second voltage to the linear regulator.

9. The wireless power sensor of claim 8, wherein the switch circuit comprises:
a delay capacitor configured to charge the second voltage to be higher than the set reference voltage; and
a switch element configured to switch on when a charged voltage charged in the delay capacitor is higher than the set reference voltage to output the second voltage to the linear regulator.

10. The wireless power sensor of claim 7, wherein the linear regulator is configured to:
convert the second voltage into the driving power voltage by dropping the second voltage by a predetermined voltage, and
output the driving power voltage to the wireless transmission controller.

11. The wireless power sensor of claim 7, wherein the wireless transmission controller comprises:
a sensing resistor configured to sense the second induced current;
an analog-to-digital (AD) converter configured to convert an analog-type current signal sensed by the sensing resistor into a digital signal; and
a data generator configured to operate by the driving power voltage to generate the measurement data corresponding to the digital signal, then transmit the measurement data to the external device.

12. The wireless power sensor of claim 11, wherein the sensing resistor is connected to both ends of the second coil.

13. A wireless power sensor, comprising:
an upper case with a current transformer configured to output a first induced current and a second induced current generated by a magnetic field induced from an alternative current (AC) power line being installed therein;
a lower case detachable from the upper case, and including a printed circuit board having an energy harvesting circuit portion configured to generate a driving power voltage by the first induced current and a wireless transmission controller configured to operate by the driving power voltage to generate measurement data corresponding to the second induced current; and
an antenna pattern configured to transmit the measurement data generated by the wireless transmission controller to an external device formed on an outer surface of the lower case.

14. The wireless power sensor of claim 13, wherein the antenna pattern is formed on at least one of outer surfaces of the lower case.

15. The wireless power sensor of claim 13, wherein the printed circuit board includes an impedance matching pattern resonating with the antenna pattern, and
wherein the antenna pattern is connected to the impedance matching pattern through a via hole formed in the lower case to transmit the measurement data at a set resonance frequency.

16. The wireless power sensor of claim 15, further comprising:
a C-Clip inserted into the lower case and configured to electrically connect the impedance matching pattern and the antenna pattern.

17. The wireless power sensor of claim 16, wherein the antenna pattern is electrically connected to the C-Clip by being brought into contact with a copper foil pattern formed on an inner side surface of the via hole, or by being brought into contact with a conductive metal inserted into the inner side surface of the via hole.

18. The wireless power sensor of claim 15, wherein the impedance matching pattern comprises an inductor corresponding to the resonance frequency, and an LC resonance circuit on which a capacitor is mounted.

19. The wireless power sensor of claim 13, wherein the current transformer includes a first coil configured to output the first induced and includes a second coil configured to output the second induced current, and
wherein the energy harvesting circuit is configured to convert the first induced current into an amplified driving power voltage for driving the wireless transmission controller.

20. The wireless power sensor of claim 13, wherein the second coil is commonly grounded with the first coil by a center tap.
